(19) United States
(12) Patent Application Publication
(10) Pub. No.: US 2026/0215584 A1
(43) Pub. Date: Jul. 30, 2026

(54) SLIDE RAIL LOCK DEVICE

(71) Applicant: FOSITEK CORPORATION, New Taipei City (TW)

(72) Inventors: Chia-Hung SU, New Taipei City (TW); Chang-Yi LI, New Taipei City (TW)

(73) Assignee: FOSITEK CORPORATION, New Taipei City (TW)

(21) Appl. No.: 19/175,664

(22) Filed: Apr. 10, 2025

(30) Foreign Application Priority Data
Jan. 24, 2025 (TW) 114103610

(51) Int. Cl. A47B 88/473; A47B 88/483; H05K 5/02

(52) U.S. Cl. CPC A47B 88/473; A47B 88/483; H05K 5/0217

(57) ABSTRACT

A slide rail lock device includes a base unit, a lock member, and a drive member, and is adapted to be disposed on a slide rail unit that includes an outer rail and an inner rail. The base unit includes a base, an inner support frame, and an outer frame that has an outer connection portion and an engagement portion. The engagement portion has an upper plate section, and a plurality of engagement sections that extend downwardly from the upper plate section. The inner support frame cooperates with the base to define a movement slot. The lock member has a lock portion that separably engages one of the engagement sections of the engagement portion. The drive member is operable to move in the movement slot to urge the lock member to rotate so that the lock portion of the lock member is disengaged from the engagement portion.

### CROSS-REFERENCE TO RELATED APPLICATION

This application claims priority to Taiwanese Invention Patent Application No. 114103610, filed on January 24, 2025, the entire disclosure of which is incorporated by reference herein.

### FIELD

The present disclosure relates to a lock device, and more particularly to a slide rail lock device.

### BACKGROUND

A conventional slide rail lock device is adapted to be mounted to a slide rail unit. The slide rail unit is disposed on a server rack cabinet, and includes an outer rail that is fixedly connected to the server rack cabinet, and an inner rail that is slidable relative to the outer rail and that is connected to a server. The slide rail lock device is disposed between the inner rail and the outer rail, and is used for preventing the inner rail from sliding out of the outer rail. The slide rail lock device includes an outer connecting frame that is fixedly connected to the outer rail, and a locking member that is pivotably connected to the inner rail and that separably engages the outer connecting frame. When the locking member engages the outer connecting frame, the inner rail is prevented from sliding out of the outer rail. When the locking member is disengaged from the outer connecting frame, the inner rail is movable relative to the outer rail and thus the server may be removed from the server rack cabinet for maintenance. However, when a maintenance worker wants to maintain the server without removing the server from the server rack cabinet, the server cannot be positioned at a particular position because the inner rail and the server that is connected to the inner rail are always movable relative to the outer rail as long as the locking member of the conventional slide rail lock device is disengaged from the outer connecting frame. In that situation, the maintenance of the server becomes more difficult and inconvenient, so there is still room for improvement.

### SUMMARY

Therefore, an object of the disclosure is to provide a slide rail lock device that can alleviate at least one of the drawbacks of the prior art.

According to the disclosure, the slide rail lock device is adapted to be disposed on a slide rail unit that includes an outer rail and an inner rail which is movable relative to the outer rail. The slide rail lock device includes a base unit and a lock unit. The base unit includes an outer frame that is adapted to be fixedly connected to the outer rail, a base that is adapted to be fixedly connected to the inner rail, and an inner support frame that is fixedly connected to the base and that cooperates with the base to define a movement slot. The outer frame has an outer connection portion that is adapted to be fixedly connected to the outer rail, and an engagement portion that extends from the outer connection portion in a direction away from the outer rail. The engagement portion has an upper plate section that is connected to the outer connection portion, and a plurality of engagement sections that extend downwardly from the upper plate section and that are spaced apart from the outer connection portion. The plurality of engagement sections are spaced apart from each other. The lock unit includes a lock member that is rotatably connected to the base, and a drive member that is connected to the lock member and that is movably disposed in the movement slot. The lock member has a lock portion that separably engages one of the engagement sections of the engagement portion. The drive member is operable to move in the movement slot to urge the lock member to rotate so that the lock portion of the lock member is disengaged from the engagement portion of the outer frame, thereby allowing the inner rail, the base, and the inner support frame to move relative to the outer rail.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a fragmentary perspective view illustrating that an embodiment of a slide rail lock device according to the present disclosure is disposed on a slide rail unit.

FIG. 2 is a fragmentary, partly exploded perspective view of an assembly of the embodiment and the slide rail unit.

FIG. 3 is an exploded perspective view of the embodiment.

FIG. 4 is an exploded perspective view of the embodiment taken from another angle.

FIG. 5 is a rear view of an inner support frame of a base unit of the embodiment.

FIG. 6 is a fragmentary rear view of the assembly, illustrating a lock portion of a lock member of a lock unit of the embodiment engaging one of engagement sections of an engagement portion of an outer frame of the embodiment.

FIG. 7 is a view similar to FIG. 6, but illustrating that the lock member is urged by a drive member of the embodiment to rotate such that the lock portion of the lock member is moved downwardly.

FIG. 8 is a view similar to FIG. 7, but illustrating that the lock member is rotated to a position in which the lock portion of the lock member is disengaged from the one of the engagement sections of the engagement portion of the outer frame.

FIG. 9 is a fragmentary rear view of the assembly, illustrating the lock portion of the lock member engaging another one of the engagement sections of the engagement portion of the outer frame.

### DETAILED DESCRIPTION

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

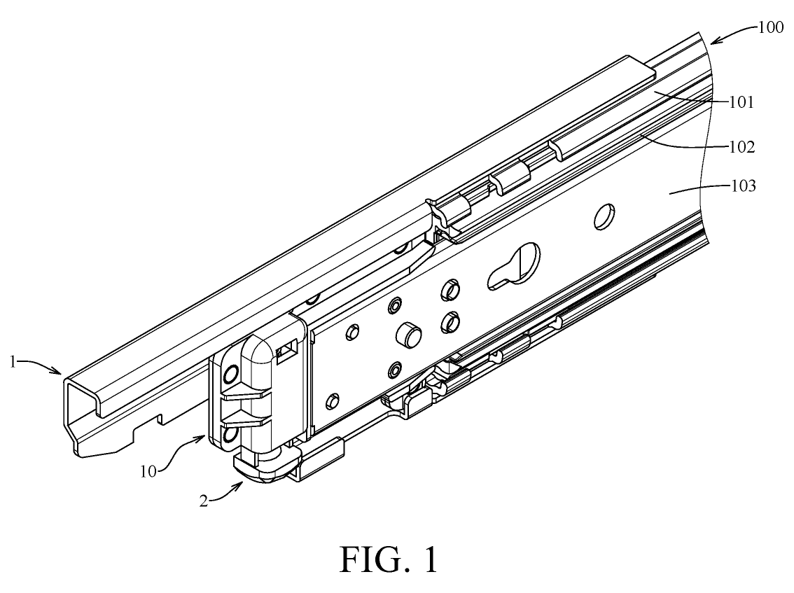

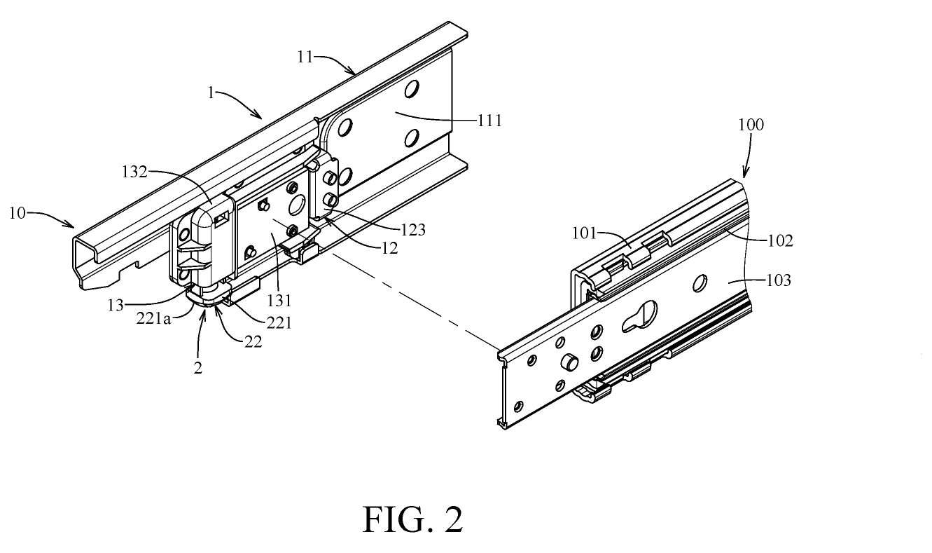

Referring to FIGS. 1 and 2, an embodiment of a slide rail lock device 10 according to the present disclosure is adapted to be disposed on a slide rail unit 100. The slide rail unit 100 is disposed on a server rack cabinet (not shown), and includes an outer rail 101, a middle rail 102 that is movably disposed on the outer rail 101, and an inner rail 103 that is movably disposed on the middle rail 102 and that is movable relative to the outer rail 101 and the middle rail 102. The outer rail 101 is fixedly connected to the server rack cabinet (not shown). The inner rail 103 is fixedly connected to a server (not shown). The slide rail lock device 10 includes a base unit 1 and a lock unit 2.

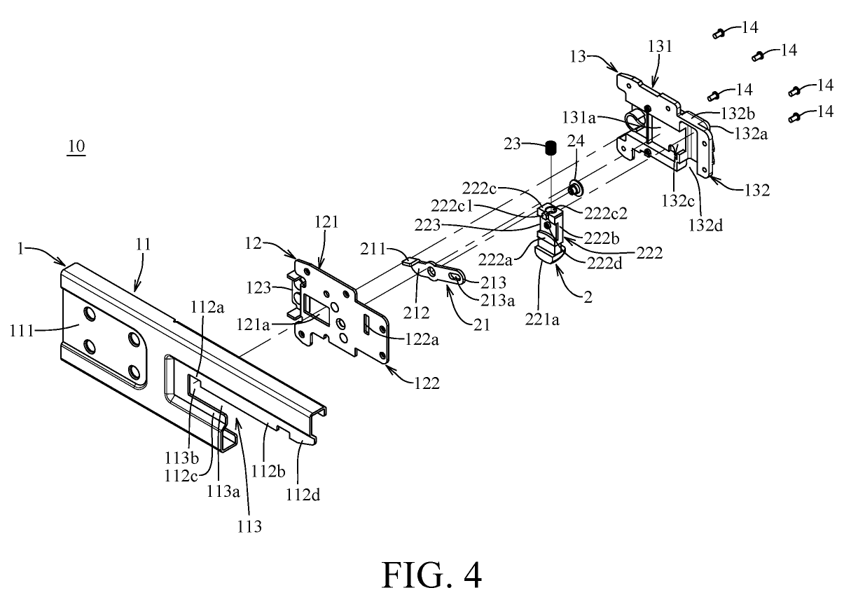

Referring to FIGS. 2 to 4, the base unit 1 includes an outer frame 11 that is adapted to be fixedly connected to the outer rail 101, a base 12 that is adapted to be fixedly connected to the inner rail 103, and an inner support frame 13 that is fixedly connected to the base 12 and that cooperates with the base 12 to define a movement slot 132d. The outer frame 11 has an outer connection portion 111 that is adapted to be fixedly connected to the outer rail 101, and an engagement portion 112 that extends from the outer connection portion 111 in a direction away from the outer rail 101. The engagement portion 112 has an upper plate section 112a that is connected to the outer connection portion 111, a plurality of engagement sections that extend downwardly from the upper plate section 112a and that are spaced apart from the outer connection portion 111, and a lower plate section 112c that is connected to the outer connection portion 111 and that is spaced apart from and located below the upper plate section 112a. In the present embodiment, the engagement sections are spaced apart from each other in a longitudinal direction of the outer rail 101, and include a first engagement section 112b that extends downwardly from the upper plate section 112a and that is spaced apart from the outer connection portion 111, and a second engagement section 112d that extends downwardly from the upper plate section 112a and that is spaced apart from the first engagement section 112b (i.e., there is a gap between the first engagement section 112b and the second engagement section 112d). It is noted that, the number of the engagement sections is not limited to the number of the engagement sections in this embodiment. In some embodiments, the number of the engagement sections may be three, four, or more, depending on actual requirements, as long as it is plural. The upper plate section 112a cooperates with the lower plate section 112c and one of the engagement sections that is closest to the outer rail 101 to define a plate groove 113. That is to say, in this embodiment, the upper plate section 112a cooperates with the lower plate section 112c and the first engagement section 112b to define the plate groove 113. The plate groove 113 has a first groove portion 113a that is defined by the first engagement section 112b and the lower plate section 112c, and a second groove portion 113b that is defined by the upper plate section 112a and the lower plate section 112c. The first groove portion 113a is in spatial communication with the second groove portion 113b, and a width of the first groove portion 113a in an up-down direction is smaller than a width of the second groove portion 113b in the up-down direction.

The base 12 has a base plate portion 121 that is rotatably connected to the lock unit 2, a guide portion 122 that is connected to one side of the base plate portion 121 which is distal to the outer rail 101, and an inner connection portion 123 that is connected to another side of the base plate portion 121 which is proximate to the outer rail 101. The base plate portion 121 is formed with a plate opening 121a. A surface of the guide portion 122 that faces the inner support frame 13 is formed with a guide groove 122a that extends in the up-down direction. The inner connection portion 123 is adapted to be fixedly connected to the inner rail 103.

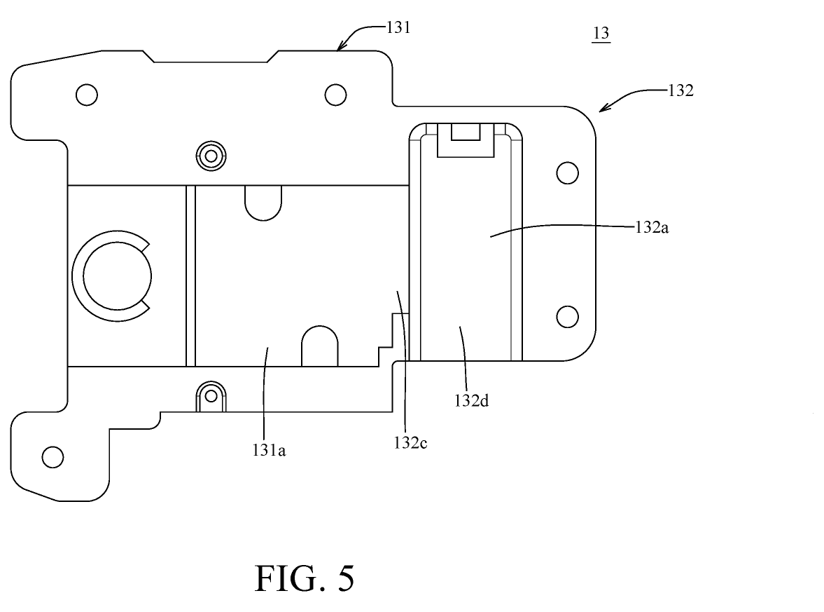

Referring to FIGS. 2 to 5, the inner support frame 13 has a cover portion 131 that is connected to the base plate portion 121, and a movement portion 132 that is connected to the cover portion 131. The cover portion 131 is connected to the base plate portion 121 by, but not limited by, five fastening members 14. The cover portion 131 is formed with an accommodation groove 131a. The movement portion 132 includes a base wall 132a and a surrounding wall 132b that extends from the base wall 132a toward the guide portion 122 of the base 12. The surrounding wall 132b is formed with a communication opening 132c that is in spatial communication with the accommodation groove 131a. The base wall 132a cooperates with the surrounding wall 132b and the guide portion 122 of the base 12 to define the movement slot 132d that opens downwardly.

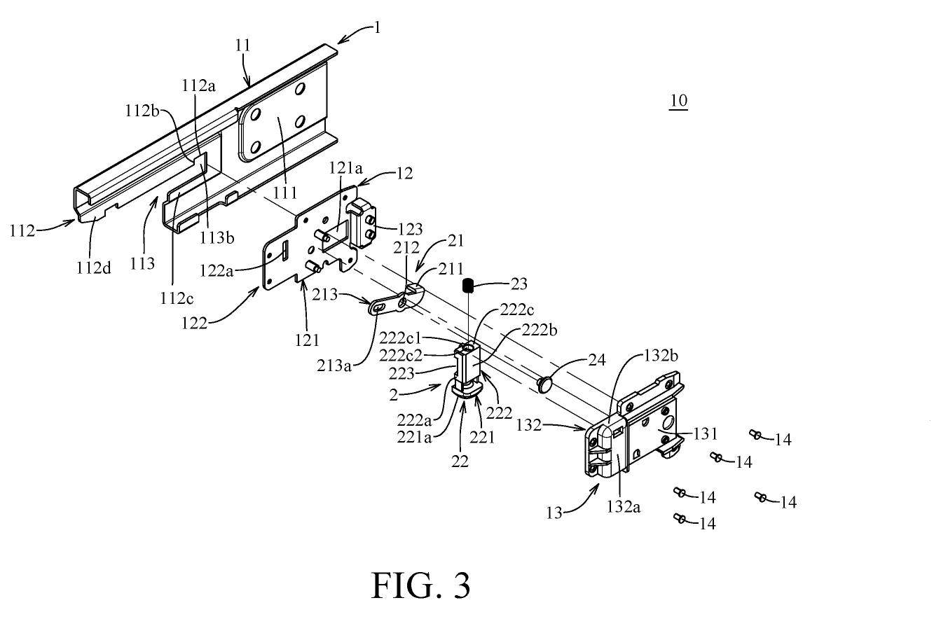

Referring to FIGS. 3 to 6, the lock unit 2 includes a lock member 21 that is rotatably connected to the base plate portion 121 of the base 12, a drive member 22 that is connected to the lock member 21 and that is movably disposed in the movement slot 132d, a resilient member 23 that is disposed between the inner support frame 13 and the drive member 22, and a rotation connecting member 24 that interconnects the lock member 21 and the base 12. The resilient member 23 is configured to be a spring. One end of the resilient member 23 abuts against the surrounding wall 132b of the movement portion 132 of the inner support frame 13, and another end of the resilient member 23 abuts against the drive member 22. The accommodation groove 131a of the cover portion 131 of the inner support frame 13 accommodates the lock member 21. The lock member 21 has a lock portion 211 that extends through the plate opening 121a of the base plate portion 121 of the base 12 to separably engages the first engagement section 112b of the engagement portion 112 of the outer frame 11 and that is movably disposed in the second groove portion 113b of the plate groove 113, a rotation portion 212 that is rotatably disposed on the base 12 and that is connected to the lock portion 211, and a linkage portion 213 that is connected to the rotation portion 212, and that extends through the communication opening 132c of the surrounding wall 132b to be connected to the drive member 22. The linkage portion 213 is formed with an elongated linkage slot 213a. The rotation portion 212 is rotatably connected to the base plate portion 121 of the base 12 by the rotation connecting member 24.

The drive member 22 is substantially in a shape of a square column, and has an operation portion 221 and a drive portion 222 that is connected to the operation portion 221. The operation portion 221 is formed with an operation surface 221a that protrudes downwardly and that is arc-shaped. In one embodiment, the operation surface 221a is hemispherical. The drive portion 222 has a bottom wall 222a that is connected to the operation portion 221, a side wall 222b that extends from the bottom wall 222a in a direction away from the operation portion 221, and a top wall 222c that is connected to the side wall 222b and that is spaced apart from the bottom wall 222a. The drive portion 222 defines a receive groove 223 that receives the linkage portion 213 of the lock member 21. The side wall 222b is formed with a linkage protrusion 222d that is movably disposed in the linkage slot 213a. A surface of the top wall 222c of the drive portion 222 of the drive member 22 that faces the base 12 is formed with a guide block 222c1 that extends in the up-down direction and into the guide groove 122a (i.e., the surface of the guide portion 122 of the base 12 that faces the inner support frame 13 also faces the drive member 22). An upper surface of the top wall 222c is formed with a top recess 222c2 that at least partially accommodates the resilient member 23.

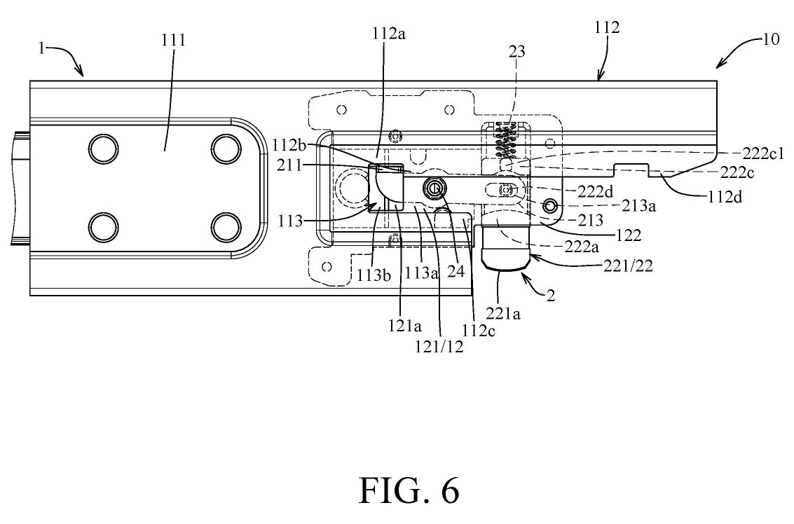

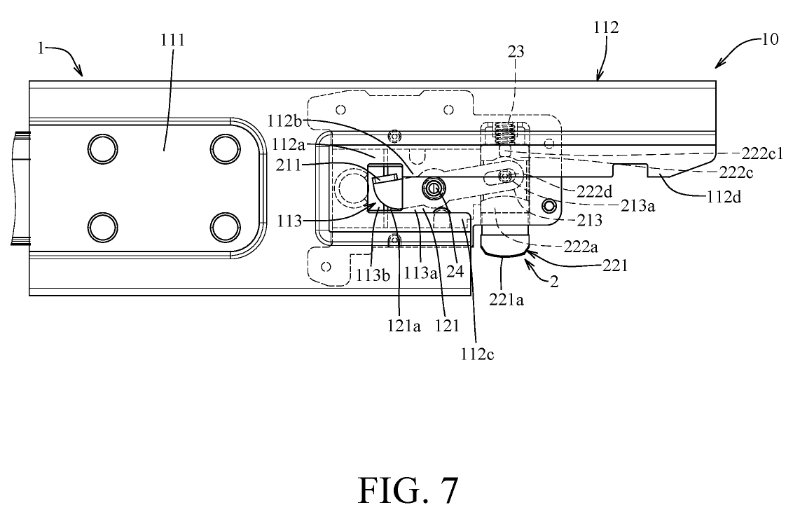

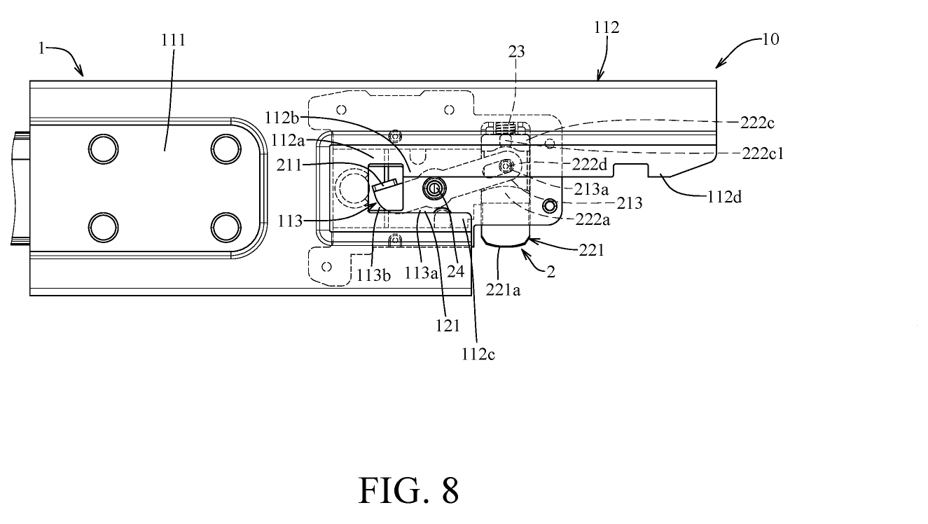

Referring to FIGS. 1, 4, 6, and 7, an operating process of the slide rail lock device 10 is described below. As shown in FIG. 6, when the drive member 22 is not operated, the lock portion 211 of the lock member 21 engages the first engagement section 112b of the engagement portion 112 of the outer frame 11 so that the inner rail 103 is prevented from sliding out of the outer rail 101. Next, when an external object (not shown) is moved toward the drive member 22 in a longitudinal direction of the slide rail unit 100 and abuts against the operation surface 221a, because the operation surface 221a protrudes downwardly and is hemispherical, the external object pushes the drive member 22 upwardly as the external object keeps moving in the longitudinal direction of the slide rail unit 100. Thus, the drive member 22 is operable to move upwardly in the movement slot 132d. By virtue of the linkage protrusion 222d of the drive portion 222 of the drive member 22 being movably disposed in the linkage slot 213a, the linkage protrusion 222d urges the linkage portion 213 of the lock member 21 to move upwardly when the drive member 22 moves upwardly in the movement slot 132d, thereby urging the lock member 21 to rotate counterclockwise (viewing from FIGS. 6 to 8). Consequently, the lock portion 211 of the lock member 21 moves downwardly in the second groove portion 113b to a position as shown in FIG. 7 and then to a position as shown in FIG. 8 such that the lock portion 211 is disengaged from the first engagement section 112b of the engagement portion 112 of the outer frame 11. At this time, the resilient member 23 is resiliently deformed.

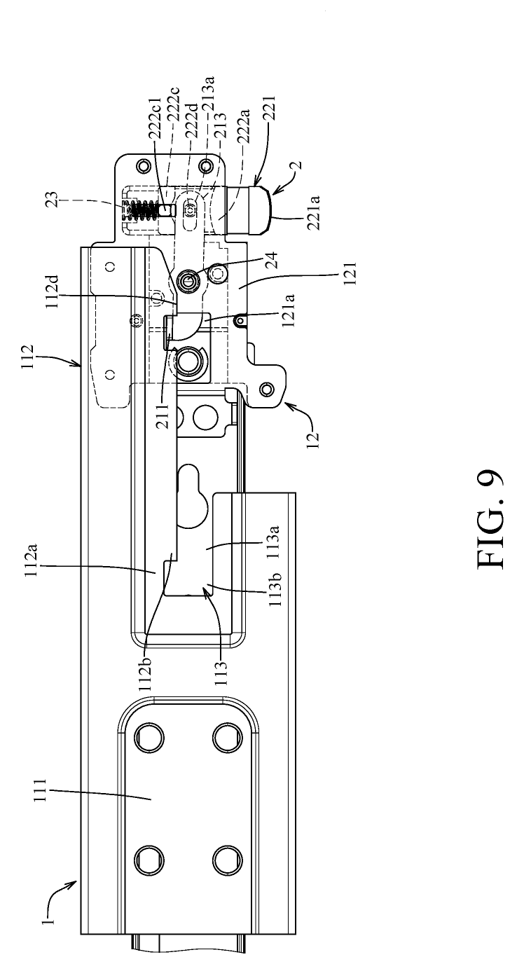

Referring to FIGS. 2, 8, and 9, the inner rail 103, the base 12, and the inner support frame 13 are allowed to move relative to the outer rail 101 after the lock portion 211 is disengaged from the first engagement section 112b of the engagement portion 112. When the lock portion 211 is disengaged from the engagement portion 112 of the outer frame 11 and when the inner rail 103, the base 12, and the inner support frame 13 are moved relative to the outer rail 101, the lock portion 211 moves past the first groove portion 113a and is separated from the outer frame 11 so that the server (not shown) that is fixedly connected to the inner rail 103 may be removed from the server rack cabinet (not shown) for maintenance. When a maintenance worker wants to maintain the server without removing the server from the server rack cabinet, the maintenance worker may urge the lock portion 211 to move to the gap between the first engagement section 112b and the second engagement section 112d of the engagement portion 112 such that the resilient member 23 restores and urges the drive member 22 to move downwardly. The linkage protrusion 222d of the drive member 22 urges the linkage portion 213 of the lock member 21 to move downwardly when the drive member 22 moves downwardly, thereby urging the lock member 21 to rotate clockwise. Consequently, as shown in FIG. 9, the lock portion 211 engages the second engagement section 112d of the engagement portion 112. At this time, the inner rail 103 and the server are only pulled out a certain distance (i.e., not completely) relative to the outer rail 101, and the base 12, the inner support frame 13, the lock member 21, the inner rail 103, and the server are ensured to be positioned at a particular position (i.e., not movable relative to the outer frame 11). Therefore, the maintenance worker may maintain the server without removing the server from the server rack cabinet, and the maintenance of the server becomes more convenient. In some embodiments, if the number of the engagement sections increases (e.g., the engagement sections further include a third engagement section and a fourth engagement section), a distance that the inner rail 103 may be pulled out is more adjustable (i.e., there are more optional positions at which the base 12, the inner support frame 13, the lock member 21, the inner rail 103, and the server may be positioned) because the lock portion 211 may engage any one of the engaging sections according to actual requirements. Thus, the slide rail lock device is flexible in use.

It should be noted that, through configurations in which the drive member 22 urges the linkage portion 213 of the lock member 21 to move upwardly via movement of the linkage protrusion 222d of the drive portion 222 of the drive member 22 in the linkage slot 213a, fit tolerance between the lock member 21 and the drive member 22 is increased. Even if lock members that are mass-produced are of unequal size, by virtue of the linkage protrusion 222d being movably disposed in the elongated linkage portion 213, the drive member 22 may still urge the linkage portion 213 to move upwardly, thereby urging any one of the unequally-sized lock members to rotate.

In summary, by virtue of the lock portion 211 of the lock member 21 of the slide rail lock device 10 being able to engage one of the engaging sections, the inner rail 103 may be pulled out for only a certain distance while positioned relative to the outer frame 11, thereby facilitating the maintenance of the server that is fixedly connected to the inner rail 103. Therefore, the purpose of the present disclosure is indeed achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A slide rail lock device adapted to be disposed on a slide rail unit that includes an outer rail and an inner rail which is movable relative to the outer rail, the slide rail lock device comprising:
a base unit including an outer frame that is adapted to be fixedly connected to the outer rail, a base that is adapted to be fixedly connected to the inner rail, and an inner support frame that is fixedly connected to the base and that cooperates with the base to define a movement slot, the outer frame having an outer connection portion that is adapted to be fixedly connected to the outer rail, and an engagement portion that extends from the outer connection portion in a direction away from the outer rail, the engagement portion having an upper plate section that is connected to the outer connection portion, and a plurality of engagement sections that extend downwardly from the upper plate section and that are spaced apart from the outer connection portion, the plurality of engagement sections being spaced apart from each other; and
a lock unit including a lock member that is rotatably connected to the base, and a drive member that is connected to the lock member and that is movably disposed in the movement slot, the lock member having a lock portion that separably engages one of the engagement sections of the engagement portion, the drive member being operable to move in the movement slot to urge the lock member to rotate so that the lock portion of the lock member is disengaged from the engagement portion of the outer frame, thereby allowing the inner rail, the base, and the inner support frame to move relative to the outer rail.

2. The slide rail lock device as claimed in claim 1, wherein the lock member further has a rotation portion that is rotatably disposed on the base and that is connected to the lock portion, and a linkage portion that is connected to the rotation portion and the drive member.

3. The slide rail lock device as claimed in claim 2, wherein the drive member has an operation portion and a drive portion that is connected to the operation portion, the drive portion having a bottom wall that is connected to the operation portion, a side wall that extends from the bottom wall in a direction away from the operation portion, and a top wall that is connected to the side wall and that is spaced apart from the bottom wall, the drive portion defining a receive groove that receives the linkage portion of the lock member.

4. The slide rail lock device as claimed in claim 3, wherein the linkage portion of the lock member is formed with an elongated linkage slot, and the side wall of the drive member is formed with a linkage protrusion that is movably disposed in the linkage slot.

5. The slide rail lock device as claimed in claim 3, wherein the base has a base plate portion that is rotatably connected to the lock member, a guide portion that is connected to one side of the base plate portion which is distal to the outer rail, and an inner connection portion that is connected to another side of the base plate portion which is proximate to the outer rail, the base plate portion being formed with a plate opening through which the lock portion of the lock member extends and engages the engagement portion of the outer frame, the guide portion and the inner support frame cooperatively defining the movement slot, the inner connection portion of the base being adapted to be fixedly connected to the inner rail.

6. The slide rail lock device as claimed in claim 5, wherein the inner support frame has a cover portion that is connected to the base plate portion, and a movement portion that is connected to the cover portion, the cover portion being formed with an accommodation groove that accommodates the lock member, the movement portion including a base wall and a surrounding wall that extends from the base wall toward the guide portion of the base, the surrounding wall being formed with a communication opening that is in spatial communication with the accommodation groove, the linkage portion of the lock member extending through the communication opening, the base wall cooperating with the surrounding wall and the guide portion of the base to define the movement slot.

7. The slide rail lock device as claimed in claim 6, wherein a surface of the guide portion of the base that faces the drive member is formed with a guide groove that extends in an up-down direction, and the top wall of the drive portion of the drive member is formed with a guide block that extends in the up-down direction and into the guide groove.

8. The slide rail lock device as claimed in claim 6, wherein the lock unit further includes a resilient member, an upper surface of the top wall of the drive portion of the drive member being formed with a top recess that at least partially accommodates the resilient member, one end of the resilient member abutting against the surrounding wall of the movement portion of the inner support frame.

9. The slide rail lock device as claimed in claim 1, wherein the engagement portion of the outer frame further has a lower plate section that is connected to the outer connection portion and that is spaced apart from and located below the upper plate section, the upper plate section cooperating with the lower plate section and one of the plurality of engagement sections that is closest to the outer rail to define a plate groove, the plate groove having a first groove portion that is defined by the lower plate section and the one of the plurality of engagement sections, and a second groove portion that is defined by the upper plate section and the lower plate section, the first groove portion being in spatial communication with the second groove portion, a width of the first groove portion in an up-down direction being smaller than a width of the second groove portion in the up-down direction, the lock portion of the lock member being movably disposed in the second groove portion, the lock portion of the lock member being operable to move past the first groove portion and to be separated from the outer frame when the lock portion is disengaged from the engagement portion of the outer frame and when the inner rail, the base, and the inner support frame are moved relative to the outer rail.
